(19) United States
(12) Patent Application Publication
(10) Pub. No.: US 2015/0263032 A1
(43) Pub. Date: Sep. 17, 2015

(54) NONVOLATILE SEMICONDUCTOR MEMORY DEVICE AND METHOD FOR MANUFACTURING SAME

(71) Applicant: KABUSHIKI KAISHA TOSHIBA, Minato-ku (JP)

(72) Inventor: Shun SHIBATA, Yokkaichi-shi (JP)

(73) Assignee: KABUSHIKI KAISHA TOSHIBA, Minato-ku (JP)

(21) Appl. No.: 14/445,358

(22) Filed: Jul. 29, 2014

Related U.S. Application Data
(60) Provisional application No. 61/951,315, filed on Mar. 11, 2014.

(51) Int. Cl. H01L 27/115; H01L 29/66; H01L 29/788; H01L 29/06; H01L 21/28; H01L 29/792; H01L 29/423

(52) U.S. Cl. CPC H01L 27/11582; H01L 29/7926; H01L 29/66833; H01L 29/42344; H01L 29/0692; H01L 21/28282; H01L 21/28273; H01L 29/42328; H01L 27/11556; H01L 29/66825; H01L 29/7883

(57) ABSTRACT

According to an embodiment, a nonvolatile semiconductor memory device includes: semiconductor regions; control gate electrodes provided on the semiconductor regions, the control gate electrodes; a charge storage layer provided in a position where each of the semiconductor regions and each of the control gate electrodes cross each other; a first insulating film provided between the charge storage layer and each of the semiconductor regions; a second insulating film provided between the charge storage layer and each of the control gate electrodes; and a select gate electrode provided on the semiconductor regions via the first insulating film, and disposed adjacent to a control gate electrode located at an end of the control gate electrodes. A distance between the control gate electrodes and a distance between the select gate electrode and the control gate electrode located adjacent to the select gate electrode are the same.

### CROSS-REFERENCE TO RELATED APPLICATIONS

This application is based upon and claims the benefit of priority from U.S. Provisional Patent Application 61/951,315, filed on Mar. 11, 2014; the entire contents of which are incorporated herein by reference.

### FIELD

Embodiments described herein relate generally to a nonvolatile semiconductor memory device and a method for manufacturing same.

### BACKGROUND

In a nonvolatile semiconductor memory device in which a plurality of NAND memory strings are arranged, the gap between NAND memory strings is becoming narrower and narrower with the progress of miniaturization.

One of the processes for processing a gate electrode in such a memory string is lithography. In such a memory string, the lithography of a memory cell region is performed, then the lithography of a select gate region is performed, and the processing of gate electrodes is performed collectively in the memory cell region and the select gate region, for example.

However, due to the necessity to consider the overlay error of the select gate region to the memory cell region, it is necessary to make the distance between the memory cell and the select gate longer than the distance between memory cells. Consequently, there is a case where the chip area is increased or the processing margin for gate processing is narrowed.

### BRIEF DESCRIPTION OF THE DRAWINGS

FIG. 1 is a schematic plan view showing a nonvolatile semiconductor memory device according to an embodiment;

FIG. 2A is a schematic cross-sectional view corresponding to the position of line A-A′ of FIG. 1, and FIG. 2B is a schematic cross-sectional view corresponding to the position of line B-B′;

FIG. 3A to FIG. 7 are schematic cross-sectional views showing the manufacturing process of a nonvolatile semiconductor memory device according to the embodiment; and

FIG. 8A to FIG. 10 are schematic cross-sectional views showing manufacturing process of a nonvolatile semiconductor memory device according to a reference example.

### DETAILED DESCRIPTION

According to an embodiment, a nonvolatile semiconductor memory device includes: a plurality of semiconductor regions extending in a first direction and arranged in a second direction crossing the first direction; a plurality of control gate electrodes provided on an upper side of the semiconductor regions, the control gate electrodes extending in the second direction, and control gate electrodes being arranged in the first direction; a charge storage layer provided in a position where each of the semiconductor regions and each of the control gate electrodes cross each other; a first insulating film provided between the charge storage layer and each of the semiconductor regions; a second insulating film provided between the charge storage layer and each of the control gate electrodes; and a select gate electrode provided on an upper side of the semiconductor regions via the first insulating film, extending in the second direction, and disposed adjacent to a control gate electrode located at an end of the control gate electrodes arranged in the first direction. A distance between adjacent ones of the control gate electrodes and a distance between the select gate electrode and the control gate electrode located adjacent to the select gate electrode are the same.

Hereinbelow, embodiments are described with reference to the drawings. In the following description, identical components are marked with the same reference numerals, and a description of components once described is omitted as appropriate.

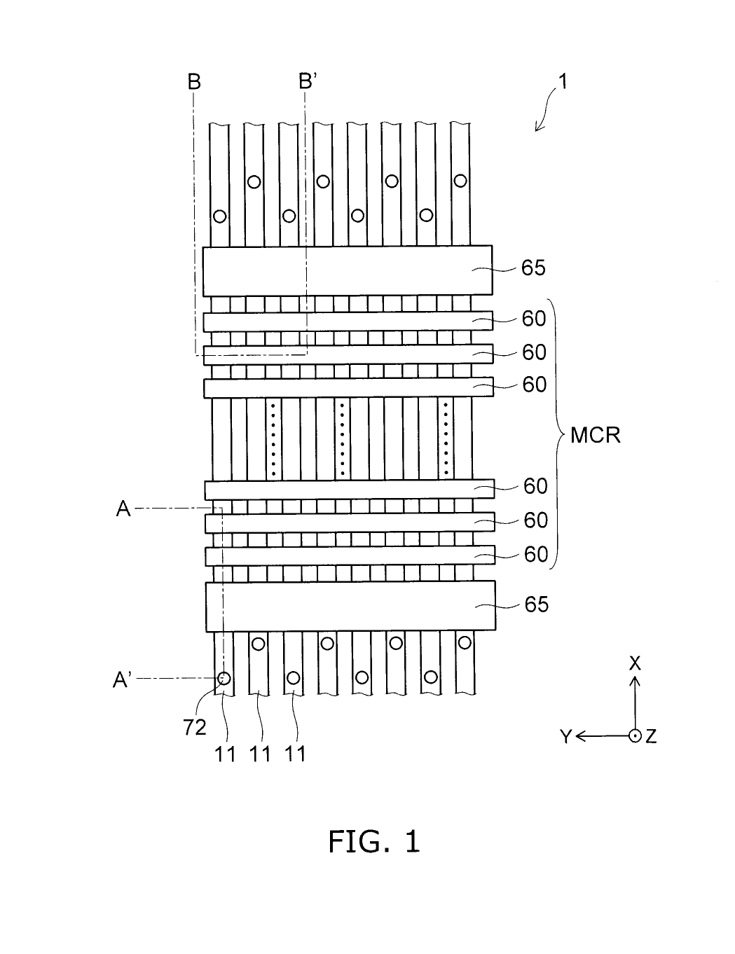

FIG. 1 is a schematic plan view showing a nonvolatile semiconductor memory device according to an embodiment.

A nonvolatile semiconductor memory device 1 according to the embodiment is a NAND flash memory. In the nonvolatile semiconductor memory device 1, a plurality of semiconductor regions 11 extend in the X-direction (a first direction), and are arranged in the Y-direction (a second direction) crossing the X-direction, for example. A plurality of control gate electrodes are provided on the upper side of the plurality of semiconductor regions 11. The plurality of control gate electrodes 60 extend in the Y-direction, and are arranged in the X-direction. A memory cell (described later) is located between each of the plurality of semiconductor regions 11 and each of the plurality of control gate electrodes 60.

A select gate electrode 65 is disposed adjacent to the control gate electrode 60 located at the end of the plurality of control gate electrodes 60 arranged. The select gate electrode 65 extends in the Y-direction.

The cross-sectional structure of the select gate electrode of the NAND string and its vicinity will now be described.

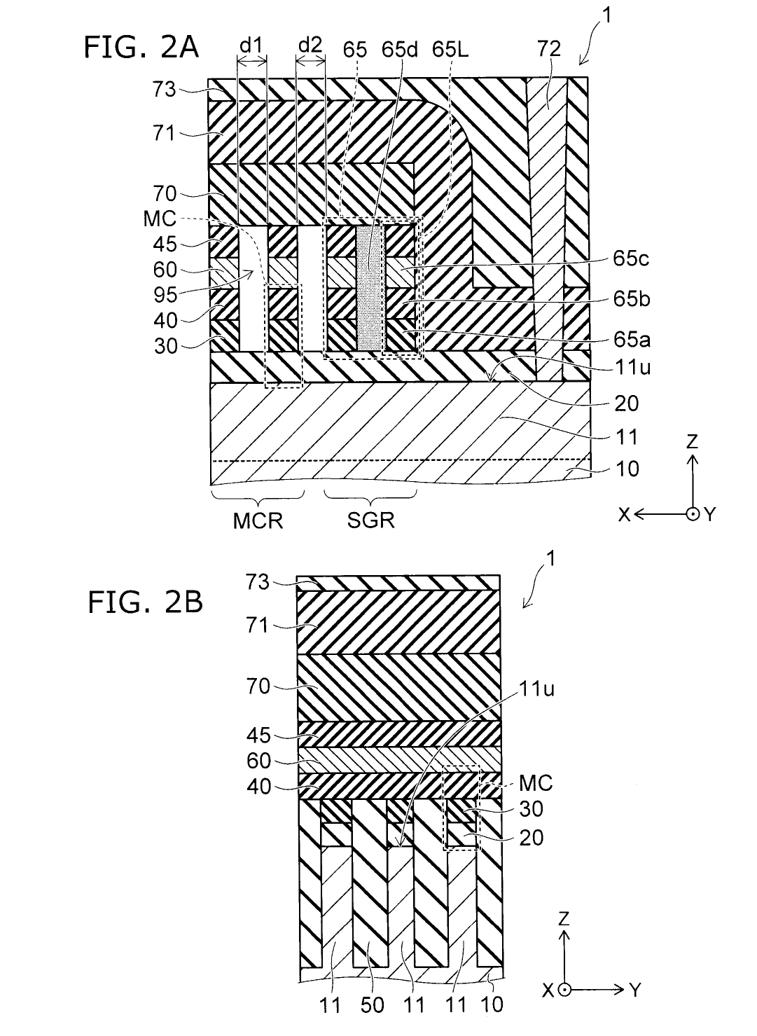

FIG. 2A is a schematic cross-sectional view corresponding to the position of line A-A′ of FIG. 1, and FIG. 2B is a schematic cross-sectional view corresponding to the position of line B-B′.

In the embodiment, the region where memory cells are disposed is referred to as a memory cell region MCR, and the region where the select gate electrode 65 is disposed is referred to as a select gate region SGR. The select gate region SGR is adjacent to the memory cell region MCR.

As shown in FIGS. 2A and 2B, the nonvolatile semiconductor memory device 1 includes the semiconductor region 11, a charge storage layer 30, a gate insulating film 20, an IPD (inter poly dielectric) insulating film 40, the control gate electrode 60, and the select gate electrode 65.

In the embodiment, the gate insulating film 20, the charge storage layer 30, the IPD insulating film 40, and the control gate electrode 60 are arranged parallel to the upper surface 11u of the semiconductor region 11; thus, the nonvolatile semiconductor memory device 1 may be referred to as a planar nonvolatile semiconductor memory device.

The plurality of semiconductor regions 11 are regions formed by a semiconductor layer 10 being separated by an element isolation region 50. The semiconductor layer 10 includes the memory cell region MCR and the select gate region SGR. The semiconductor region 11 is an active area that the transistor of the nonvolatile semiconductor memory device 1 occupies. The semiconductor region 11 is a p-type semiconductor region, for example.

The charge storage layer 30 is provided on the gate insulating film 20. The charge storage layer 30 is provided in a position where each of the plurality of semiconductor regions 11 and each of the plurality of control gate electrodes 60 cross each other. The charge storage layer 30 can store a charge that has tunneled from the semiconductor region 11 via the gate insulating film 20. The charge storage layer 30 may be a structure using a floating gate, or a silicon nitride film in a MONOS structure, not limited to a floating gate.

The gate insulating film 20 is provided on the semiconductor region 11. The gate insulating film 20 is provided between the charge storage layer 30 and each of the plurality of semiconductor regions 11. The gate insulating film 20 allows a charge (for example, electrons) to tunnel between the semiconductor region 11 and the charge storage layer 30. The IPD insulating film 40 is provided between the charge storage layer 30 and each of the plurality of control gate electrodes 60.

The control gate electrode 60 functions as a gate electrode for writing a charge on the charge storage layer 30 or reading a charge written in the charge storage layer 30.

A unit including the gate insulating film 20, the charge storage layer 30, and the IPD film 40 provided in a position where the semiconductor region 11 and the control gate electrode 60 cross each other is referred to as a memory cell MC.

A space 95 is provided between control gate electrodes 60 adjacent in the X-direction, between the IPD insulating films 40 provided under the adjacent control gate electrodes 60 and adjacent in the X-direction, and between the charge storage layers 30 provided under the adjacent IPD insulating films 40 and adjacent in the X-direction. By providing the space 95 between memory cells MC, the parasitic capacitance between memory cells MC is reduced.

The select gate electrode 65 is provided on the upper side of the plurality of semiconductor regions 11 via the gate insulating film 20. The select gate electrode 65 is disposed adjacent to the control gate electrode 60 located at the end of the plurality of control gate electrodes 60 arranged in the X-direction.

The distance d1 between adjacent control gate electrodes 60 and the distance d2 between the select gate electrode 65 and the control gate electrode 60 located adjacent to the select gate electrode 65 are the same.

The select gate electrode 65 includes a plurality of stacked bodies 65L extending in the Y-direction and arranged in the X-direction. Each of the plurality of stacked bodies 65L includes a first layer 65a made of the same components as the charge storage layer 30, a second layer 65b provided on the first layer 65a and made of the same components as the IPD insulating film 40, and a third layer 65c provided on the second layer 65b and made of the same components as the control gate electrode 60.

In the nonvolatile semiconductor memory device 1, the pitch of the plurality of stacked bodies 65L arranged in the X-direction and the pitch of the plurality of control gate electrodes 60 arranged in the X-direction are the same.

A conductive layer 65d is provided between adjacent stacked bodies 65L. The conductive layer 65d is in contact with the gate insulating film 20. The conductive layer 65d contains polysilicon or a metal (for example, tungsten (W)). A cap film 45 is provided on each of the plurality of control gate electrodes 60 and on the third layer 65c. The conductive layer 65d is in contact with the cap film 45.

To reduce the resistance of the select gate electrode 65, the volume of the conductive layer 65d is preferably increased. Hence, in the embodiment, the cap film 45 is provided on the third layer 65c, and the conductive layer 65d is brought in contact with the cap film 45.

An interlayer insulating film 70 is provided on the cap film 45, and further an interlayer insulating film 71 is provided on the interlayer insulating film 70 and on the gate insulating film 20. Further, an interlayer insulating film 73 is provided on the interlayer insulating film 71. A contact electrode 72 connected to the semiconductor region 11 is provided next to the select gate electrode 65.

The material of the semiconductor layer 10 (the semiconductor region 11) is silicon, for example. The material of the gate insulating film 20 is silicon oxide (SiOₓ) or the like, for example.

The IPD film 40 and the cap film 45 may be a single layer of a silicon oxide film or a silicon nitride film, or may be a film in which either a silicon oxide film or a silicon nitride film is stacked, for example. The IPD film 40 may be what is called an ONO film (silicon oxide film/silicon nitride film/silicon oxide film), for example.

In the case where the charge storage layer 30 is a floating gate layer, the material of the charge storage layer 30 is polysilicon (poly-Si) or the like, for example.

The material of the control gate electrode 60 is tungsten, tungsten nitride, or the like, for example.

Unless otherwise specified, in the embodiment, the material of portions referred to as element isolation regions, insulating films, insulating layers, or mask layers is silicon oxide (SiOₓ), silicon nitride (SiNₓ), or the like, for example.

The material of the contact electrode 72 is tungsten, for example.

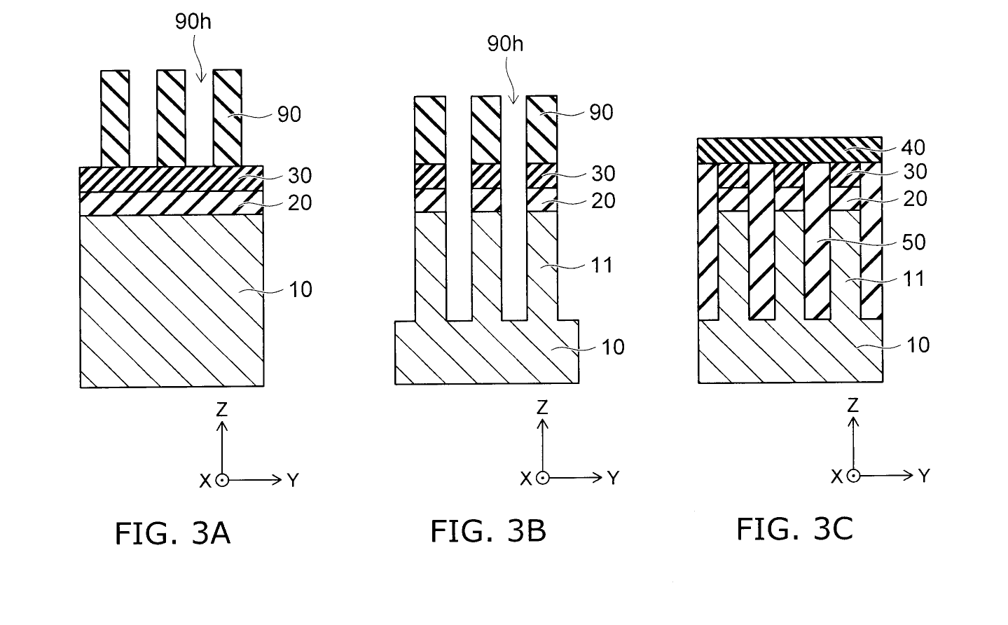

FIG. 3A to FIG. 7 are schematic cross-sectional views showing the manufacturing process of a nonvolatile semiconductor memory device according to the embodiment.

First, FIG. 3A to FIG. 3C show a cross section corresponding to the position of line B-B′ described above. As shown in FIG. 3A, the gate insulating film 20 and the charge storage layer 30 that are not patterned are formed in this order on the semiconductor layer 10.

Subsequently, a plurality of mask layers 90 extending in the X-direction and arranged in the Y-direction are formed on the IPD insulating film 40.

Next, as shown in FIG. 3B, RIE (reactive ion etching) is performed on the charge storage layer 30, the gate insulating film 20, and a surface portion of the semiconductor layer 10 exposed from the plurality of mask layers 90 and located under an opening 90h of the mask layer 90. After the RIE, the film thickness of the mask layer 90 has become thinner than before the RIE because what is called film thinning has occurred due to the RIE.

In this stage, the surface portion of the semiconductor layer 10 is separated into a plurality of parts, and a plurality of semiconductor regions 11 extending in the X-direction and arranged in the Y-direction are formed in the surface portion. The gate insulating film 20 is formed on each of the plurality of semiconductor regions 11, and the charge storage layer 30 is formed on the gate insulating film 20. The plurality of semiconductor regions 11 include the memory cell region MCR where memory cells are disposed and the select gate region SGR where the select gate electrode is disposed adjacent to the memory cell region MCR.

Next, as shown in FIG. 3C, the element isolation region 50 is formed between semiconductor regions 11, between gate insulating films 20, and between charge storage layers 30, which are adjacent in the Y-direction. The mask layer 90 is removed. Subsequently, the IPD insulating film 40 is formed.

Also an example in which the element isolation region 50 is not formed in order to reduce the parasitic capacitance between memory cells MC is included in the embodiment.

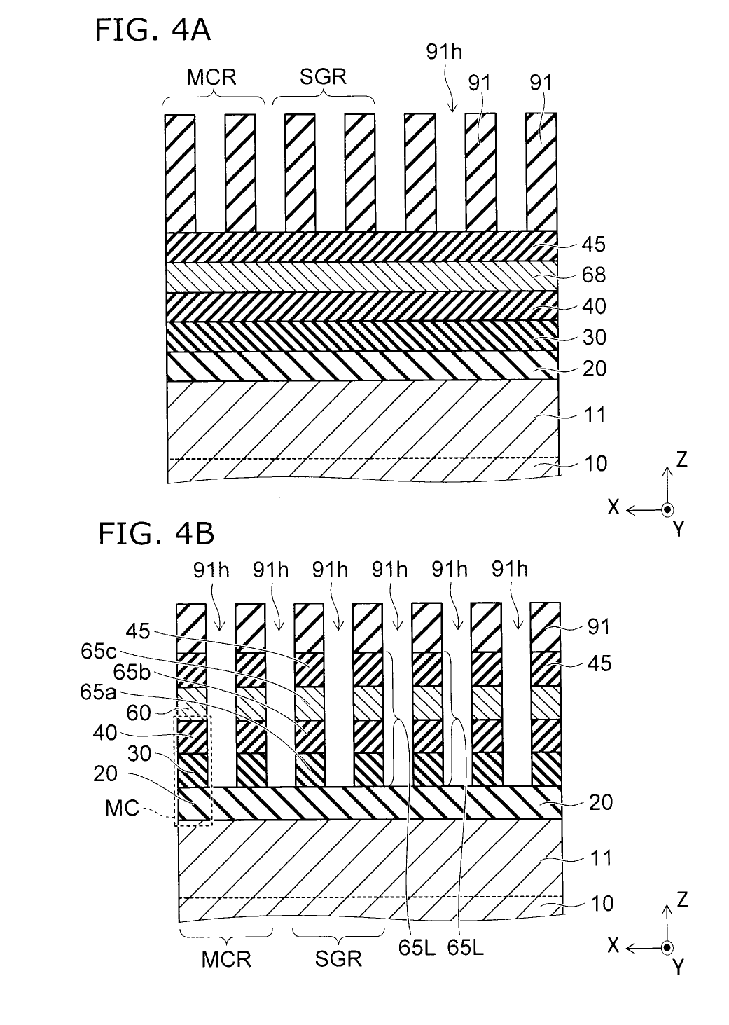

In and after FIG. 4A, a cross section in the position of line A-A′ described above is shown. In other words, in and after FIG. 4A, a cross section in which FIG. 3C is rotated 90 degrees in the X-Y plane is shown.

Next, as shown in FIG. 4A, a conductive layer 68 is formed on the upper side of the semiconductor layer 10 via the plurality of semiconductor regions 11, the gate insulating film 20, the charge storage layer 30, and the IPD insulating film 40. The cap film 45 is formed on the conductive layer 68. The cap film 45 may be removed as necessary. In this case, the pitch in the X-direction and the length in the Y-direction of a mask layer 91 are not changed.

Subsequently, a plurality of mask layers 91 extending in the Y-direction and arranged in the X-direction with the same pitch are formed on the conductive layer 68 via the cap film 45. The mask layer 91 is formed in the memory cell region MCR and the select gate region SGR.

In the manufacturing process, the cap film 45 functions as a stopper film in CMP (chemical mechanical polishing) processing described later.

Next, as shown in FIG. 4B, the cap film 45 exposed from the mask layer 91 and the conductive layer 68 under an opening 91h of the mask layer 91 are removed by RIE to separate the conductive layer 68 in the X-direction. Further, the IPD insulating film 40 and the charge storage layer 30 under the opening 91h of the mask layer 91 are removed.

In the embodiment, this RIE is performed collectively in the memory cell region MCR and the select gate region SGR. After the RIE, the film thickness of the mask layer 91 has become thinner than before the RIE because what is called film thinning has occurred due to the RIE.

In this stage, in the memory cell region MCR, a plurality of control gate electrodes 60 formed by being separated from the conductive layer 68 are formed. The plurality of control gate electrodes 60 extend in the Y-direction, and are arranged in the X-direction.

In the memory cell region MCR, the memory cell MC including the gate insulating film 20, the charge storage layer 30, and the IPD insulating film 40 is formed in a position where each of the plurality of semiconductor regions 11 and each of the plurality of control gate electrodes 60 cross each other.

On the other hand, in the select gate region SGR, a plurality of stacked bodies 65L are formed. The plurality of stacked bodies 65L are arranged in the X-direction.

The stacked body 65L is formed on the gate insulating film 20, and includes the first layer 65a made of the same components as the charge storage layer 30, the second layer 65b formed on the first layer 65a and made of the same components as the IPD insulating film 40, the third layer 65c formed on the second layer 65b and made of the same components as the control gate electrode 60, and the cap film 45. Here, the third layer 65c is a layer formed by being separated from the conductive layer 68, and extends in the Y-direction.

The pitch of the memory cell MC in the X-direction and the pitch of the stacked body 65L are the same. This is because the memory cell MC and the stacked body 65L have been processed using the mask layers 91 extending in the Y-direction and arranged in the X-direction with the same pitch.

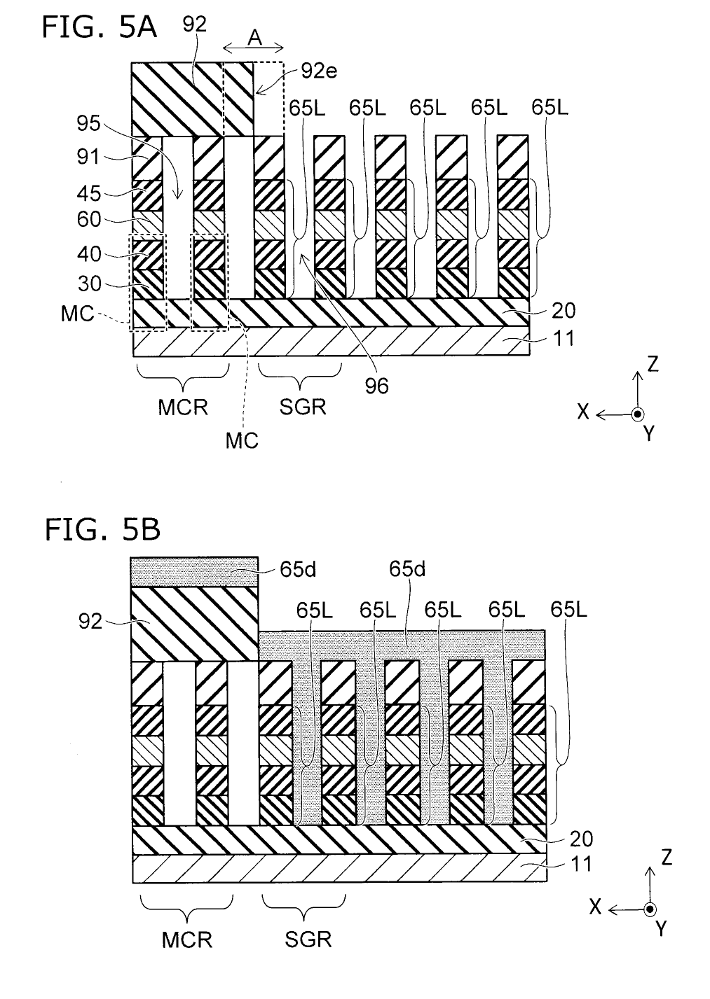

Next, as shown in FIG. 5A, a mask layer 92 that does not cover the stacked body 65L disposed in the select gate region SGR and covers the mask layer 91 in the memory cell region MCR is formed. Here, the mask layer 92 is formed under conditions of less good step coatability. As a result, the mask layer 92 is not formed between memory cells MC adjacent in the X-direction, and is formed on the upper side of the mask layer 91. In other words, in the memory cell region MCR, an insulating film is formed so as to cover the upper side of the plurality of stacked bodies without filling the portion between stacked bodies (memory cells) adjacent in the X-direction

Thereby, the space 95 is formed between adjacent memory cells MC.

The mask layer 92 needs only to expose the space 96 between adjacent stacked bodies 65L, and the outer edge 92e of the mask layer 92 may be located in the select gate region SGR. In the drawing, the range of the position of the outer edge 92e of the mask layer 92 is shown by arrow A.

Next, as shown in FIG. 5B, the conductive layer 65d is formed on the mask layer 92 and between stacked bodies 65L in the select gate region by a method of one of the sputtering method, CVD (chemical vapor deposition), plating, etc. In this stage, the mask layer 92 is not formed between adjacent memory cells MC, and the mask layer 92 is formed on the memory cell MC; therefore, the conductive layer 65d is not formed between adjacent memory cells MC. Thus, the space 95 remains between adjacent memory cells MC.

In this stage, at least the conductive layer 65d is formed between a first stacked body 65L that is formed in the select gate region SGR adjacent to the stacked body formed in the memory cell region MCR in the X-direction and a second stacked body 65L that is formed in the select gate region SGR adjacent to the first stacked body 65L in the X-direction.

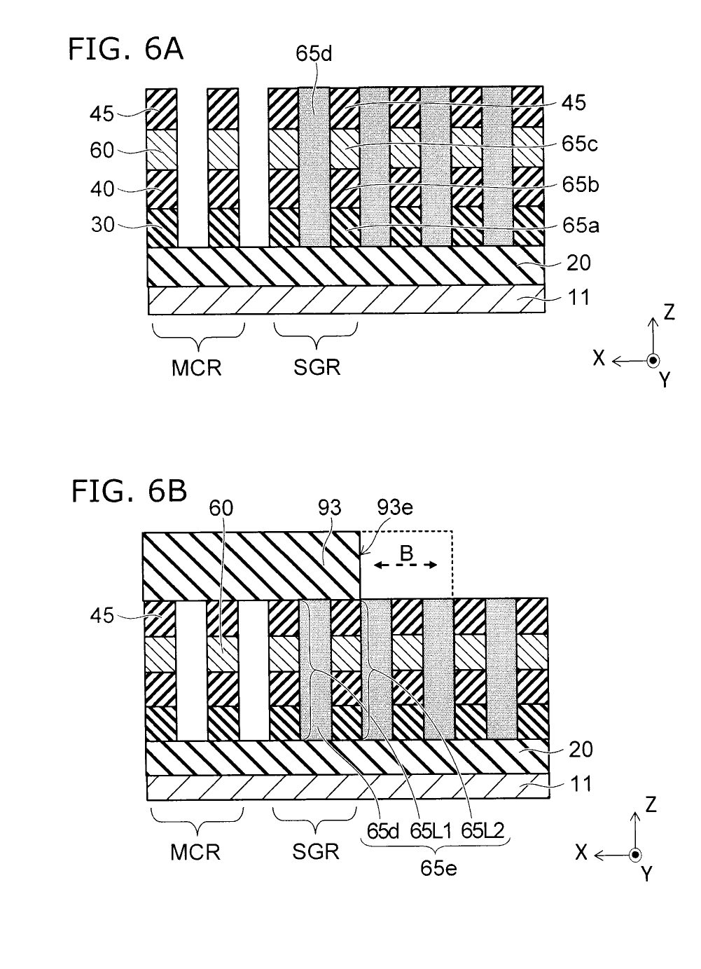

Next, as shown in FIG. 6A, the surplus coating film formed on the upper side of the cap film 45 is removed by CMP processing. In the CMP processing, the cap film 45 functions as a stopper film of CMP. The conductive layer 65d extends from the gate insulating film 20 to the cap film 45 between stacked bodies 66L.

Next, as shown in FIG. 6B, in order to form the select gate electrode 65 from a structure body 65e that is composed of a stacked body 65L1 disposed adjacent to the control gate electrode 60 located at the end of the plurality of control gate electrodes 60 arranged in the X-direction, the conductive layer 65d in contact with the stacked body 65L1, and a stacked body 65L2 in contact with the conductive layer 65d on the opposite side to the stacked body 65L1, a mask layer 93 is formed on the structure body 65e and on the cap film 45 in the memory cell region MCR. At this time, the mask layer 93 is formed under conditions of less good step coatability. As a result, the mask layer 93 is not formed between memory cells MC adjacent in the X-direction, and the space 95 remains between adjacent memory cells MC.

The end 93e of the mask layer 93 may be shifted as appropriate in accordance with the width of the gate electrode 65 of the objective, like arrow B, for example.

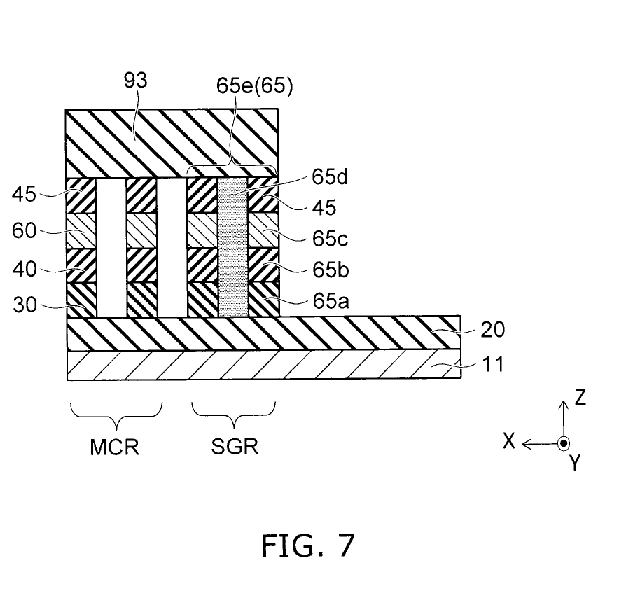

Next, as shown in FIG. 7, the stacked body 65L and the conductive layer 65d other than the structure body 65e described above are removed from on the gate insulating film 20 by RIE.

Thereby, the select gate electrode 65 including the first layer 65a, the second layer 65b, the third layer 65c, and the conductive layer 65d is formed in the select gate region SGR.

The example in which the structure body 65e described above is made into the select gate electrode 65 is only an example. The length of the select gate electrode 65 in the X-direction may be adjusted as appropriate in order to suppress the short channel effect of the select gate electrode 65, for example. Stacked bodies 65L and conductive layers 65d larger in number than the stacked bodies 65L and the conductive layer 65d included in the structure body 65e may be left, and a select gate electrode 65 composed of these stacked bodies 65L and conductive layers 65d may be formed, for example.

After that, the mask layer 93 is left as the interlayer insulating film 70, the interlayer insulating films 71 and 72 are formed on the interlayer insulating film 70 and on the gate insulating film 20 as shown in FIG. 2A and FIG. 2B, and the contact electrode 72 connected to the semiconductor region 11 is formed.

Although in FIG. 5A the space 95 is formed between adjacent memory cells MC, an insulating layer may be buried in the space. Thereby, slurry used for CMP processing does not sink between memory cells MC during the CMP processing, and contamination of the memory cell MC due to the slurry is prevented.

Before describing effects of the embodiment, the manufacturing process of a nonvolatile semiconductor memory device according to a reference example is described.

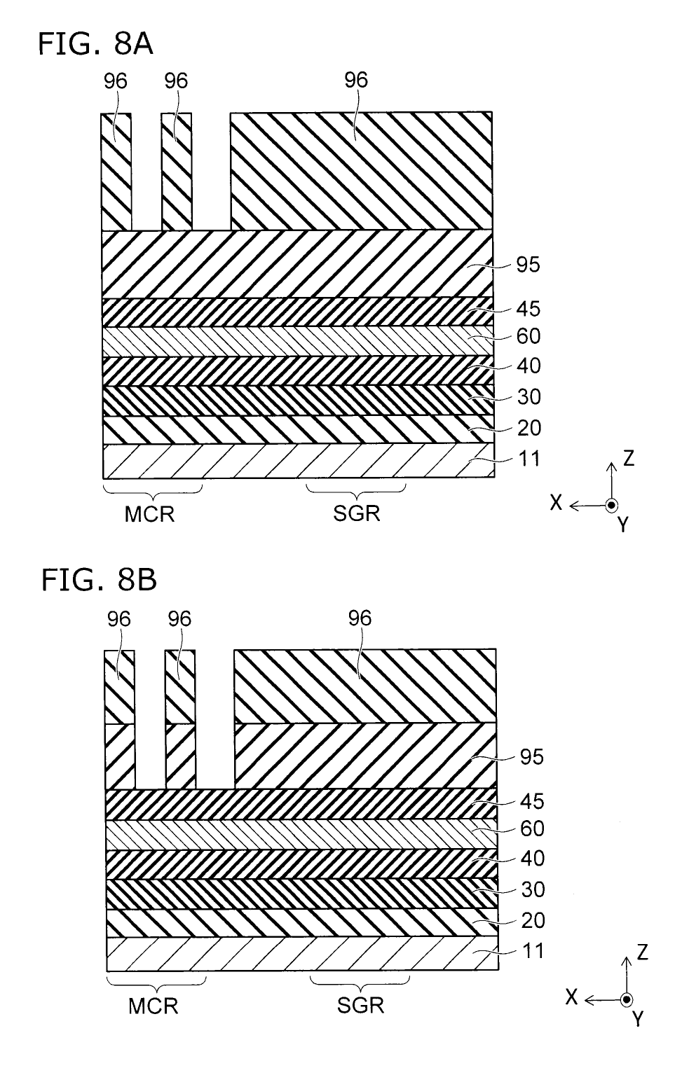

FIG. 8A to FIG. 10 are schematic cross-sectional views showing the manufacturing process of a nonvolatile semiconductor memory device according to the reference example.

With the progress of miniaturization of NAND flash memories, the overlay error of the lithography process is becoming more significant. Here, the overlay error is the misalignment in superposition between layers in the X-direction or the Y-direction.

Hence, in the manufacturing process according to the reference example illustrated below, the lithography process for forming a mask layer for processing the memory cell region MCR and the lithography process for forming a mask layer for processing the select gate region SGR are advanced in two separate processes.

For example, as shown in FIG. 8A, in the memory cell region MCR, a plurality of mask layers 96 extending in the Y-direction and arranged in the X-direction are formed on a mask layer 95. Subsequently, as shown in FIG. 8B, the mask layer 96 is used to pattern the mask layer 95 by RIE.

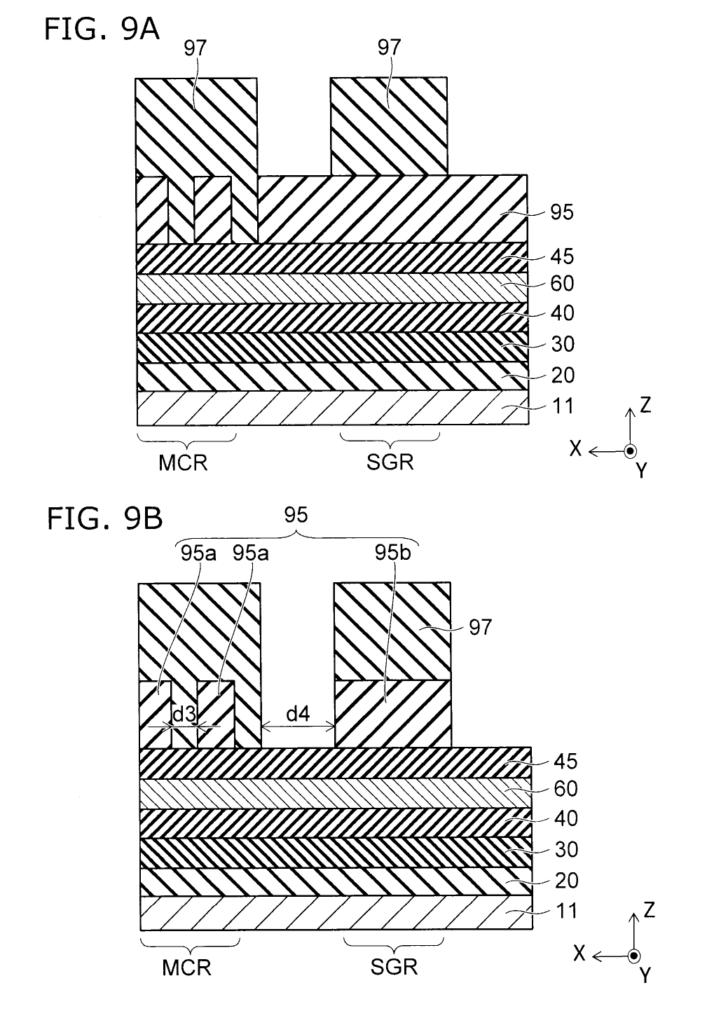

Next, as shown in FIG. 9A, in the select gate region SGR, a mask layer 97 extending in the Y-direction is formed. Subsequently, as shown in FIG. 9B, the mask layer 97 is used to pattern the mask layer 95 by RIE.

Here, the mask layer 95 provided in the memory cell region MCR is referred to as a mask layer 95a, and the mask layer 95 provided in the select gate region SGR is referred to as a mask layer 95b.

In the reference example, the lithography process in the memory cell region MCR of the mask layer 95 and the lithography process in the select gate region SGR are performed in two separate processes. In these lithography processes, the patterning of the mask layer is performed so that the gap d4 between the mask layer 95a and the mask layer 95b is wider than the gap d3 between mask layers 95a in the memory cell region MCR.

This is because the overlay error of the select gate region SGR to the memory cell region MCR has been considered. In other words, this is because controlling the gap d4 to the same width as the narrow gap d3 in the lithography process is difficult under the situation of the progressing miniaturization of NAND flash memories. In other words, the reference example has the negative effect of increase in chip area.

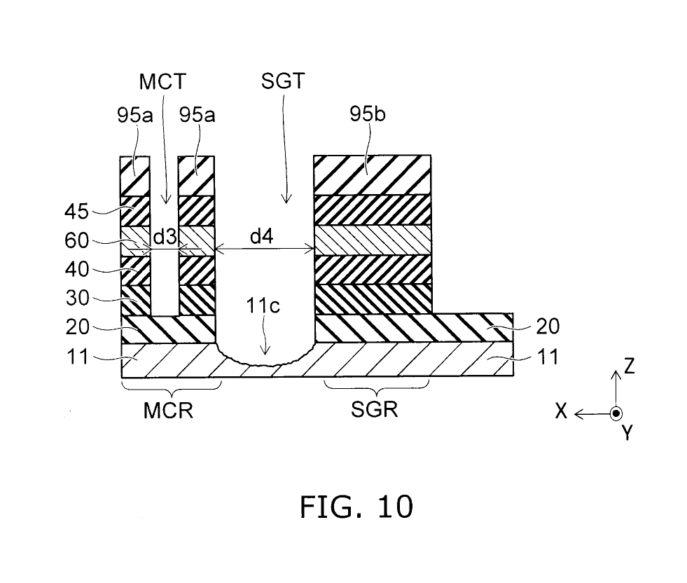

In this state, as shown in FIG. 10, RIE processing is performed collectively in the memory cell region MCR and the select gate region SGR. That is, in the memory cell region MCR and the select gate region SGR, RIE processing is performed on the cap film 45 exposed from the mask layer 95a and the mask layer 95b, and the conductive layer 68, the IPD film 40, and the charge storage layer 30 under the exposed portion of the cap film 45.

However, the gap d4 is wider than the gap d3, and the rates of supplying etching gas reaching the bottoms of trenches MCT and SGT are different. Consequently, the gouging phenomenon in which the bottom of the trench SGT is dug deeper than the bottom of the trench MCT (the formation of a recess 11c) may occur.

If such a recess 11c has been formed, the resistance R of the semiconductor region 11 between the memory cell region MCR and the select gate region SGR is increased, and a sufficient current may not flow through the memory string even when the select gate electrode 65 is switched to ON.

In contrast, in the embodiment, a plurality of memory cells MC and a plurality of stacked bodies 65L are formed collectively using a plurality of mask layers 91 extending in the Y-direction and arranged in the X-direction with the same pitch. Therefore, the distance d1 between adjacent memory cells MC and the distance d2 between the stacked body 65L and the memory cell MC are made the same, and the rates of supplying etching gas reaching the bottoms of the trenches MCT and SGT are made the same. Thereby, the gouging phenomenon described above is less likely to occur.

The select gate electrode 65 according to the embodiment includes the conductive layer 65d with a low resistivity, and the conductive layer 65d is formed to penetrate through the second layer 65b and reach the cap film 45 and the gate insulating film 20. By leaving the cap film 45 on the control gate electrode 50, the length of the conductive layer 65d in the Z-direction is increased in accordance with the thickness of the cap film 45. Therefore, the resistance of the select gate electrode 65 itself is lowered, and switching characteristics by the select gate electrode 65 become good.

In the nonvolatile semiconductor memory device 1 according to the embodiment, since the distance d1 between adjacent memory cells MC and the distance d2 between the stacked body 65L and the memory cell MC are the same, the chip area is smaller than in the reference example.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile semiconductor memory device comprising:
a plurality of semiconductor regions extending in a first direction and arranged in a second direction crossing the first direction;
a plurality of control gate electrodes provided on an upper side of the semiconductor regions, the control gate electrodes extending in the second direction, and control gate electrodes being arranged in the first direction;
a charge storage layer provided in a position where each of the semiconductor regions and each of the control gate electrodes cross each other;
a first insulating film provided between the charge storage layer and each of the semiconductor regions;
a second insulating film provided between the charge storage layer and each of the control gate electrodes; and
a select gate electrode provided on an upper side of the semiconductor regions via the first insulating film, extending in the second direction, and disposed adjacent to a control gate electrode located at an end of the control gate electrodes arranged in the first direction,
a distance between adjacent ones of the control gate electrodes and a distance between the select gate electrode and the control gate electrode located adjacent to the select gate electrode being the same.

2. The device according to claim 1, wherein
the select gate electrode includes a plurality of stacked bodies arranged in the first direction on each of the semiconductor regions and
each of the stacked bodies includes:
a first layer made of the same components as the charge storage layer;
a second layer provided on the first layer, and the second layer being made of the same components as the second insulating film; and
a third layer provided on the second layer, and the third layer being made of the same components as the control gate electrode.

3. The device according to claim 2, wherein a pitch of the stacked bodies arranged in the first direction and a pitch of the control gate electrodes arranged in the first direction are the same.

4. The device according to claim 2, wherein a conductive layer is provided between adjacent ones of the stacked bodies.

5. The device according to claim 4, wherein the conductive layer includes polysilicon or a metal.

6. The device according to claim 1, wherein a space is provided between ones of the control gate electrodes adjacent in the first direction, is provided between ones of the second insulating films provided under each of the adjacent control gate electrodes in the first direction, and is provided between ones of the charge storage layers provided under each of the adjacent second insulating films in the first direction.

7. The device according to claim 4, further comprising a third insulating film on each of the control gate electrodes and on the third layer.

8. The device according to claim 7, wherein the conductive layer is in contact with the third insulating film.

9. A method for manufacturing a nonvolatile semiconductor memory device comprising:
separating a surface portion of a semiconductor layer into a plurality of parts to form a plurality of semiconductor regions in the surface portion, the semiconductor regions extending in a first direction, semiconductor regions being arranged in a second direction crossing the first direction, and semiconductor regions having a memory cell region where a memory cell is to be disposed and a select gate region where a select gate electrode is to be disposed adjacent to the memory cell region, and forming the first insulating film on each of the semiconductor regions, a charge storage layer on the first insulating film, and a second insulating film on the charge storage layer;
forming a first conductive layer on an upper side of the semiconductor layer via the semiconductor regions, the first insulating film, the charge storage layer, and the second insulating film;
forming a plurality of mask layers on the first conductive layer, the mask layers extending in the second direction and being arranged in the first direction with the same pitch;
removing the first conductive layer, the second insulating film, and the charge storage layer under an opening of the mask layer to form a plurality of electrode layers formed by separating the first conductive layer, the electrode layers extending in the second direction, and the electrode layers arranged in the first direction and form a plurality of stacked bodies including the first insulating film, the charge storage layer, and the second insulating film in a position where each of the semiconductor regions and each of the electrode layers cross each other; and
forming a second conductive layer between adjacent ones of the stacked bodies in the select gate region.

10. The method according to claim 9, wherein in the forming the second conductive layer, at least the second conductive layer is formed between a first stacked body formed in the select gate region adjacent to the stacked body formed in the memory cell region in the first direction and a second stacked body formed in the select gate region adjacent to the first stacked body in the first direction.

11. The method according to claim 9, wherein in the memory cell region, a fourth insulating film is formed so as to cover an upper side of the stacked bodies without filling a portion between ones of the stacked bodies adjacent in the first direction.

12. The method according to claim 9, further comprising forming a third insulating film on an upper side of the first conductive layer after the forming the first conductive layer, a plurality of mask layers are formed on the third insulating film in forming the mask layers, and the mask layers extend in the second direction and being arranged in the first direction with the same pitch.

13. The method according to claim 9, wherein the first and second conductive layers contain polysilicon or a metal.

14. The method according to claim 12, wherein the second conductive layer in the select gate region is formed in forming the second conductive layer, and the second conductive layer reaches the third insulating film between adjacent ones of the stacked bodies.
